(19) United States
(12) Patent Application Publication
(10) Pub. No.: US 2023/0420511 A1
(43) Pub. Date: Dec. 28, 2023

(54) STACKED SINGLE CRYSTAL TRANSITION-METAL DICHALCOGENIDE USING SEEDED GROWTH

(71) Applicant: Intel Corporation, Santa Clara, CA (US)

(72) Inventors: Carl H. NAYLOR, Portland, OR (US); Kirby MAXEY, Hillsboro, OR (US); Kevin P. O'BRIEN, Portland, OR (US); Chelsey DOROW, Portland, OR (US); Sudarat LEE, Hillsboro, OR (US); Ashish Verma PENUMATCHA, Beaverton, OR (US); Uygar E. AVCI, Portland, OR (US); Matthew V. METZ, Portland, OR (US); Scott B. CLENDENNING, Portland, OR (US); Chia-Ching LIN, Portland, OR (US); Carly ROGAN, North Plains, OR (US); Arnab SEN GUPTA, Hillsboro, OR (US)

(21) Appl. No.: 17/850,623

(22) Filed: Jun. 27, 2022

(51) Int. Cl. H01L 29/06; H01L 29/778; H01L 29/786; H01L 29/18; H01L 21/02

(52) U.S. Cl. CPC H01L 29/0673; H01L 29/778; H01L 29/78696; H01L 21/02568; H01L 21/02645; H01L 21/02598; H01L 21/02485; H01L 29/18

(57) ABSTRACT

Embodiments described herein may be related to apparatuses, processes, systems, and/or techniques for a transistor structure that includes stacked nanoribbons as a single crystal or monolayer, such as a transition metal dichalcogenide (TMD) layer, grown on a silicon wafer using a seeding material. Other embodiments may be described and/or claimed.

### FIELD

Embodiments of the present disclosure generally relate to the field of transistor manufacturing, and in particular to stacked layer channels.

### BACKGROUND

Continued growth in virtual machines, cloud computing, and portable devices will continue to increase the demand for high density transistors within chips and packages.

### BRIEF DESCRIPTION OF THE DRAWINGS

FIG. 1 illustrates a legacy example of a wafer with a partially grown transition metal dichalcogenide (TMD) layer and examples of electrical connections on the TMD layer.

FIG. 2 illustrates a top-down and cross section side view of a wafer with multiple TMD layers grown using multiple seeds, in accordance with various embodiments.

FIGS. 3A-3S illustrate stages in a manufacturing process for creating a transistor structure that has stacked TMD layers as channels, in accordance with various embodiments.

FIG. 4 illustrates another example transistor structure with stacked TMD layers as channels with sources and drains, in accordance with various embodiments.

FIGS. 5A-5B schematically illustrate a top view of an example die in wafer form and in singulated form, and a cross section side view of a package assembly, in accordance with various embodiments.

FIG. 6 is an example process for manufacturing a wafer with multiple seeds and multiple TMD layers growing from the seeds, in accordance with various embodiments.

FIG. 7 illustrates a computing device in accordance with one implementation of the invention.

FIG. 8 illustrates an interposer that includes one or more embodiments of the invention.

### DETAILED DESCRIPTION

Embodiments described herein may be related to apparatuses, processes, systems, and/or techniques directed to the manufacturing of a transistor structure that includes stacked 2D channels, which may be referred to as nanoribbons or as nanowires. These stacked channels may be implemented as single crystal TMD layers, which may be single crystal layers or monolayers. In embodiments, these single crystal TMD layers are grown on a wafer, such as a silicon wafer, using a seeding material. In embodiments, this technique for growing a single crystal TMD layer may produce a continuous layer that has no growth boundaries within the layer. In embodiments, multiple seeds may be used to grow multiple single crystal TMD layers, each with no growth boundaries, on the wafer.

In embodiments, after the initial single crystal TMD layer is grown, subsequent layers of sacrificial material and additional single crystal TMD layers may be formed on top of the initial single crystal TMD layer. This process may be repeated to create a stack of single crystal TMD layers. In embodiments, each of these single crystal TMD layers may be grown from the same seed, which have a height above a surface of the wafer that is at least as high as the height of the final transistor structure.

In embodiments, 2D materials, such as TMDs, provide a replacement for silicon when used in transistor structure channels. In particular, TMDs implemented as monolayers allow for shorter gate lengths by enabling thinner channels, which may be difficult to do with silicon due to scattering effects due to intrinsic poor performance of silicon at a thin body thickness. In legacy implementations, a chemical vapor deposition (CVD) process may be used on a wafer to grow TMD monolayers. This legacy process includes the processing of metal oxides and chalcogen precursors that lead to vapor phase reaction followed by the formation of a stable 2D TMD over the wafer using metal oxide CVD (MOCVD) growth. Deposition and/or formation of additional layers may then follow. However, this legacy process results in non-single crystal TMD growth, which results in grain boundaries within the TMD that are detrimental to device performance.

Embodiments described herein include seeded growth techniques for growing single crystal TMD layers on a wafer for transistor nanoribbons that are precisely grown and stacked on top of each other, using a same seed material that is on the wafer. In addition, these embodiments enable high-performance single crystal TMD layers that do not have grain boundaries.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

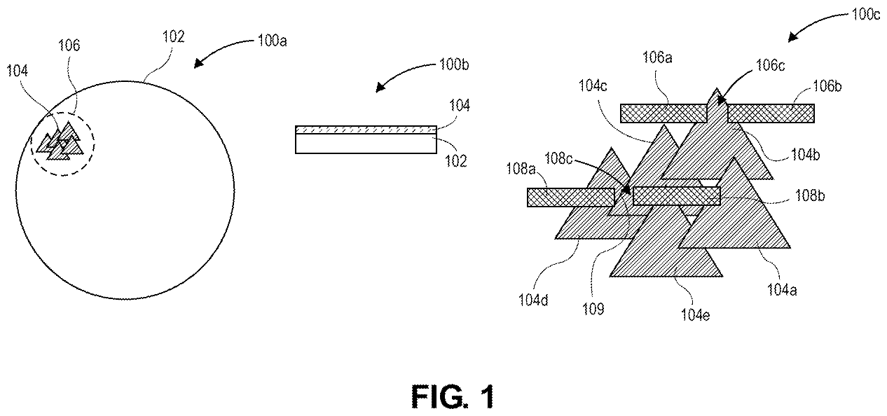

FIG. 1 illustrates a legacy example of a wafer with a partially grown TMD layer and examples of electrical connections on the TMD layer. Diagram 100a shows a top-down view of a wafer 102 that has a legacy TMD layer 104 grown on a portion 106 of the surface of the wafer 102. In the legacy implementation, the TMD layer 104 has been grown using legacy MOCVD techniques across the wafer 102. Diagram 100b shows a cross section side view of the wafer 102 and the TMD layer 104 on the wafer 102. Note the diagram 100a shows a portion of the TMD layer 104, where in legacy implementations the TMD layer 104 may substantially or entirely cover the wafer 102.

Diagram 100c shows a zoomed-in portion 106 of the surface of the wafer 102. Individual triangular-shaped TMD crystals 104a-104e make up a portion of the TMD layer 104. As a result, the legacy TMD layer 104 is not a single crystal TMD growth. As a result, performance may not be uniform for devices that include electrical connections that are subsequently placed on the wafer. For example, consider the area 106c between a first electrical connection 106a and a second electrical connection 106b. Because the area 106c falls within the crystal structure of TMD crystal 104b, the performance of the device using the first electrical connection 106a and second electrical connection 106b will be better and more reliable.

In contrast, an area 108c between a third electrical connection 108a and a fourth electrical connection 108b may be compromised, because a boundary 109 that separates TMD crystal 104c from TMD crystal 104d passes through the area 108c. As a result, the performance of the device using the third electrical connection 108a and the fourth electrical connection 108d may be compromised. Grain boundaries may be detrimental to device performance and create variations from device to device.

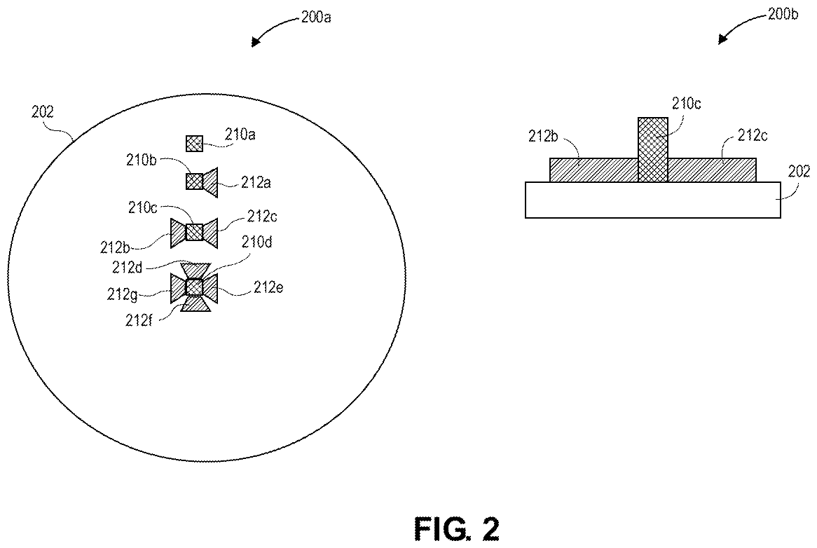

FIG. 2 illustrates a top-down and cross section side view of a wafer with multiple TMD layers grown using multiple seeds, in accordance with various embodiments. Diagram 200a shows a top-down view of a wafer 202 that includes a plurality of seeds 210a-210d that are placed on the surface of a wafer 202. Diagram 200a is not in proportion, and the number of seeds in embodiments used in production may be vastly greater. As embodiment examples, a TMD single crystal structure 212a grows from a side of seed 210b, two TMD single crystal structures 212b, 212c grow from sides of seed 210c, and four TMD single crystal structures 212d-212g grow from each side of seed 210d. Diagram 200b shows a cross section side view of the wafer 202 with seed 210c on the surface of the wafer 202, and TMD single crystal structures 212b, 212c growing from the seed 210c.

In embodiments, material used for the wafer may include silicon. In embodiments, material used for the seed may include a tungsten oxide (WOx) or a molybdenum oxide (MoOx). In embodiments, material used for the TMD may include molybdenum disulfide (MoS₂), Molybdenum diselenide (MoSe₂), tungsten disulfide (WS₂), and tungsten diselenide (WSe₂), hexagonal boron nitride (h-BN), borophene (2D boron), silicene (2D silicon), germanene (2D germanium), and MXenes (2D carbides/nitrides).

In embodiments, a direction of or channeling of growth of the TMD single crystal structures 212d-212g on the surface of the wafer 202 may be facilitated by the use of dams (not shown) and/or various positions of seeds 210a-210d. In embodiments, a shape of a TMD single crystal structure may be modified during subsequent processing by etching, for example to etch a nano-ribbon shape.

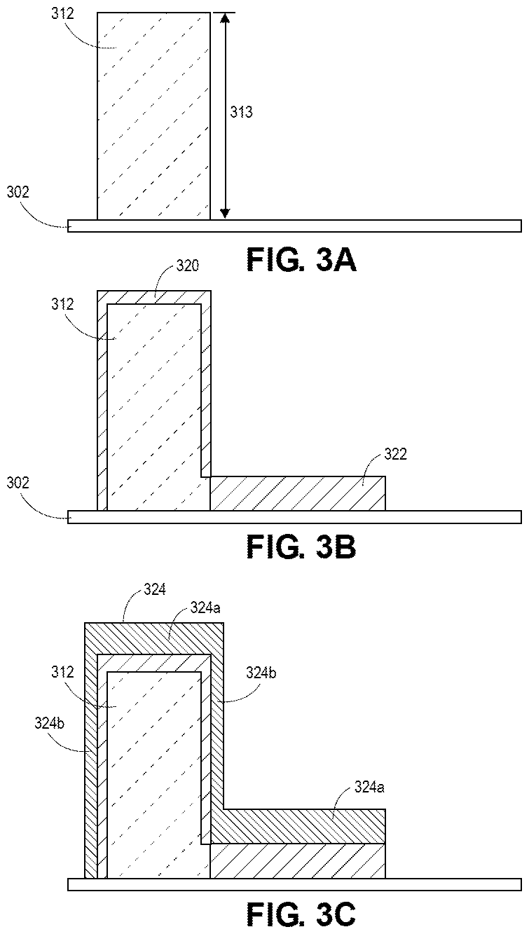

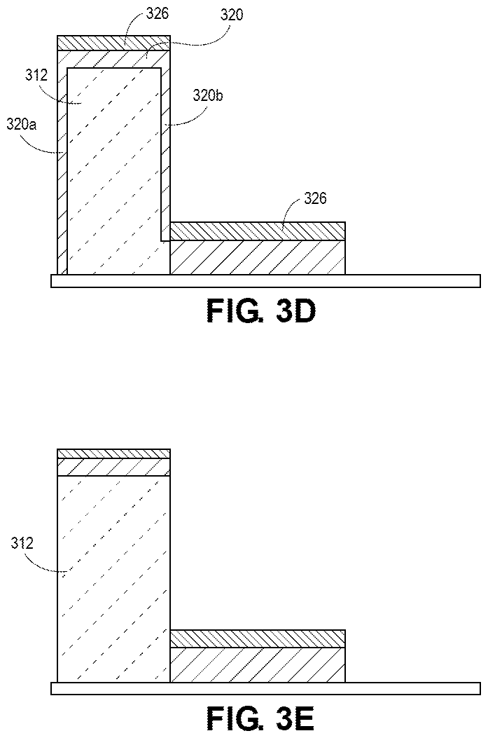

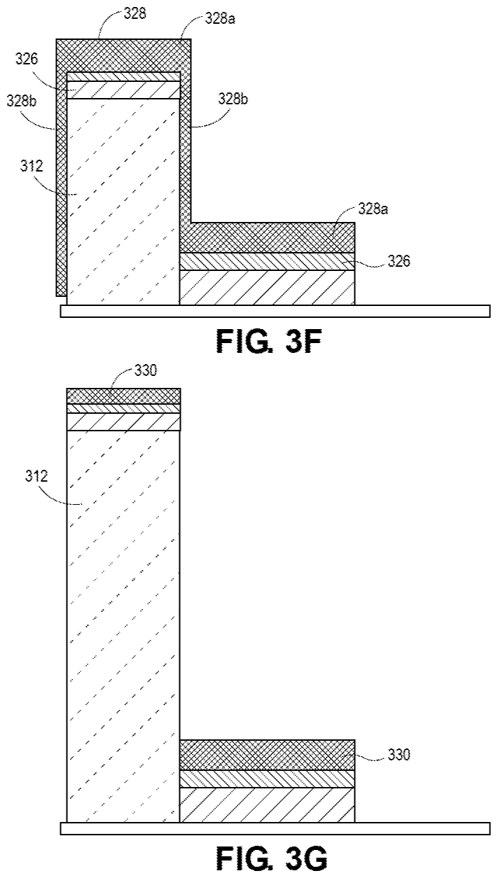

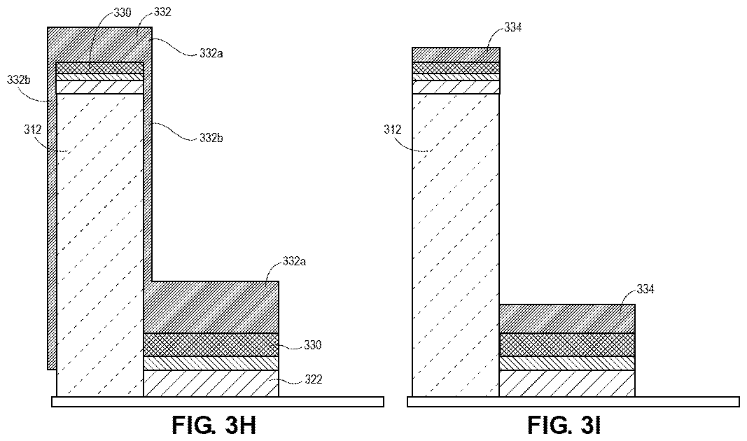

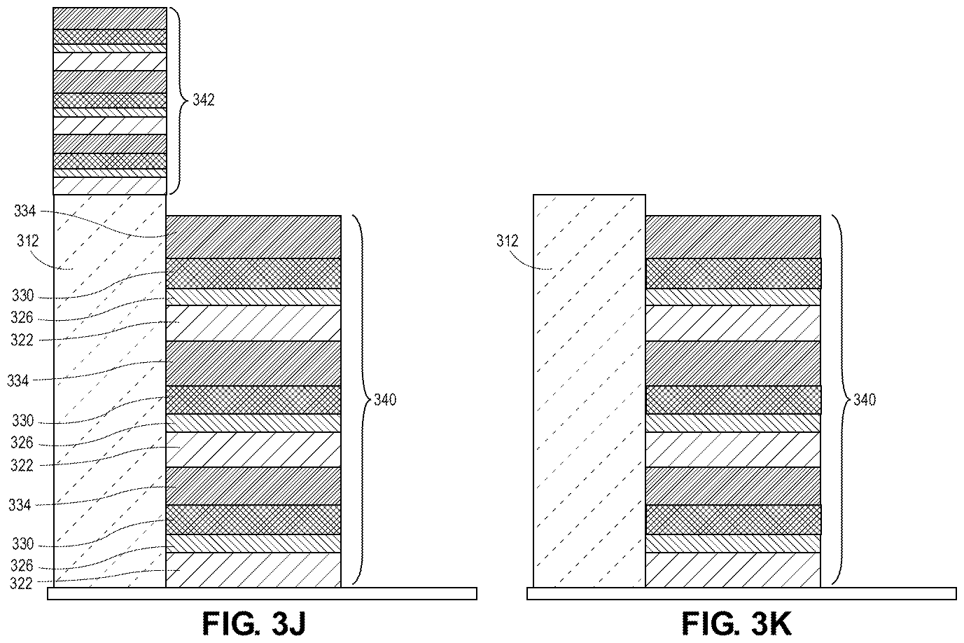

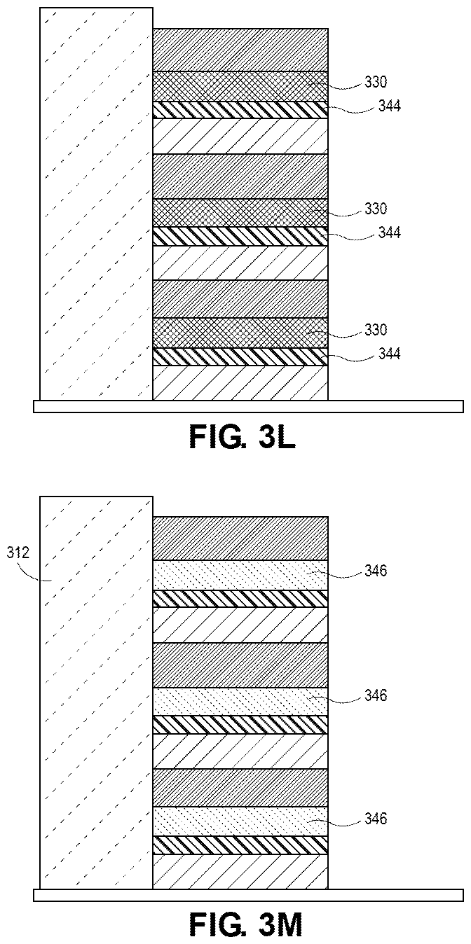

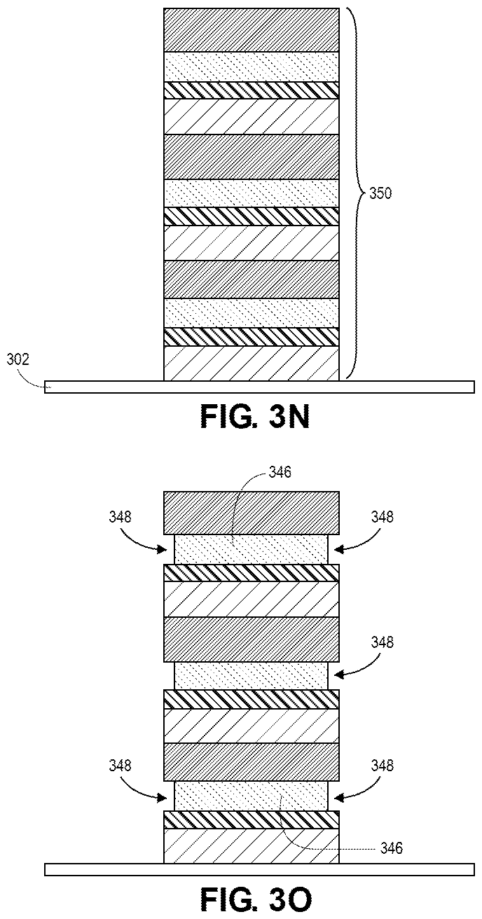

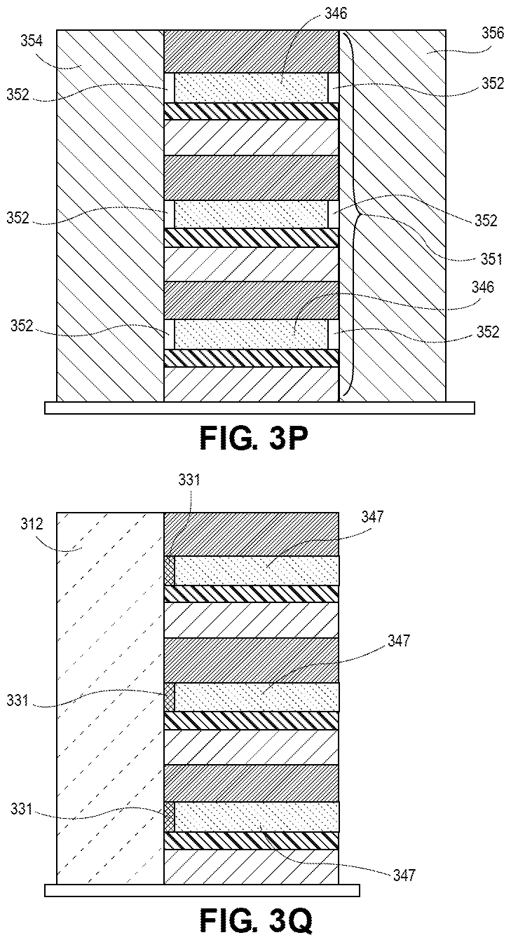

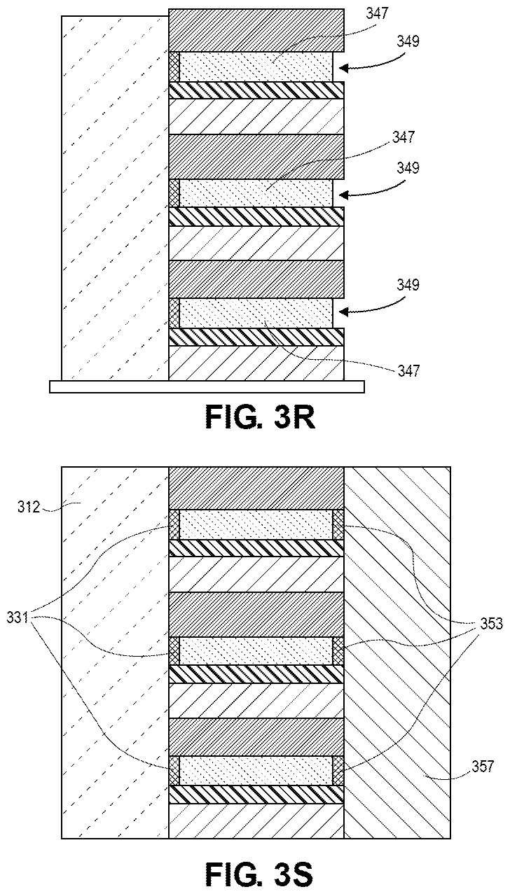

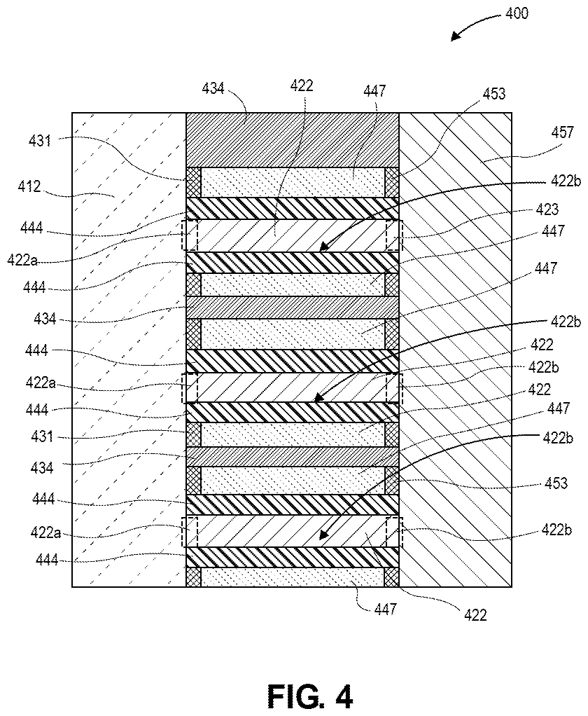

FIGS. 3A-3S illustrate stages in a manufacturing process for creating a transistor structure that has stacked TMD layers as channels, in accordance with various embodiments. These stages in the manufacturing process may rely on systems, apparatus, techniques, and/or processes described above with respect to FIGS. 1-2. FIG. 3A shows a cross section side view of a stage in the manufacturing process where a wafer 302 is provided, and a seed 312, is placed on the wafer 302. In embodiments, the wafer 302 may be similar to wafer 202 and seed 312 may be similar to seeds 210a-210d of FIG. 2. A height 313 of the seed 312 from a surface of the wafer 302 may be selected based upon the resulting height of the transistor structure, for example a transistor structure such as shown in FIGS. 3P, 3S or FIG. 4. In embodiments, the height may be nm.

FIG. 3B shows a stage in the manufacturing process where a TMD material is grown to form a TMD layer 322 on the surface of the wafer 302 that is adjacent to the seed 312. As part of the growth process, TMD layer 320 may form around the seed 312. In embodiments, the resulting growth of crystals within TMD layer 322 and TMD layer 320 may be substantially different. For example, TMD layer 320 that is on a surface of the seed 312 may have a smaller crystalline structure as compared to the TMD layer 322. The larger crystalline structure of TMD layer 322 may be more suitable for channels material within a transistor structure. In embodiments TMD layer 322 may be a single crystal, and TMD layer 320 may be a polycrystalline because it would be grown via metal transformation resulting in small crystals with no control of grain boundaries.

In embodiments, prior to the TMD material 322 being grown on the wafer 302, a growth promoter material (not shown), which may include one or more of carbon rings or sodium, may be placed in order to promote the growth of the TMD material 322 on the wafer 302. In embodiments, the growth promoter material (not shown) may be placed on any surface onto which TMD material, such as TMD material 322, is grown.

FIG. 3C shows a stage in the manufacturing process where a first sacrificial layer 324 is applied to the TMD layer 320 and the TMD layer 322. In embodiments, a thickness of the first sacrificial layer 324a that is on a top of the seed 312 and on top of the TMD layer 322 may be thicker than a thickness of the first sacrificial layer 324b that is on the sides of the seed 312.

FIG. 3D shows a stage in the manufacturing process where an etch is performed to remove the thinner first sacrificial layer 324b on the sides of the seed 312, thus exposing TMD layer sides 320a, 320b of the TMD layer 320. In embodiments, the etch will also modify the first sacrificial layer 326, which is now thinner than the first sacrificial layer 324a of FIG. 3C.

FIG. 3E shows the stage in the manufacturing process where an etch is performed to remove the TMD layer 320a, 320b of FIG. 3D that surrounds the seed 312, leaving the sides of seed 312 exposed.

FIG. 3F shows a stage in the manufacturing process where a second sacrificial layer 328 is applied, with a thicker second sacrificial layer 328a over the first sacrificial layer 326, and on a top of the seed 312, and a thinner second sacrificial layer 328b around the sides of the seed 312. In embodiments, similar to the first sacrificial layer 324, the thickness of the second sacrificial layer 328a may be thicker than the thickness of the second sacrificial layer 328b on the sides of the seed 312.

FIG. 3G shows a stage in the manufacturing process where an etch is performed to remove the thinner second sacrificial layer 328b on the sides of the seed 312. In embodiments, the etch will also modify the second sacrificial layer 330, which is now thinner than the second sacrificial layer 328a of FIG. 3F.

FIG. 3H shows a stage in the manufacturing process where a dielectric 332 is applied. Note that a thickness of the dielectric layer 332b on the sides of the seed 312 is thinner than a thickness of the dielectric layer 332a on top of the seed 312 and on top of the TMD layer 322.

FIG. 3I shows a stage in the manufacturing process where an etch is performed to remove the thinner dielectric layer 332b on the sides of the seed 312. In embodiments, the etch will also modify the dielectric layer 334, which is now thinner than the dielectric layer 332a of FIG. 3H.

FIG. 3J shows a stage in the manufacturing process where the stages described in FIGS. 3B-3I are performed multiple times to create an interim transistor structure stack 340 that includes TMD layers 322, first sacrificial layers 326, second sacrificial layers 330 and dielectric layers 334. A temporary stack 342, which may be similar to interim transistor structure stack 340, is created on top of the seed 312.

FIG. 3K shows a stage in the manufacturing process where the temporary stack 342 on seed 312 of FIG. 3J is removed. In embodiments, an etching process may be used.

FIG. 3L shows a stage in the manufacturing process where the first sacrificial layer 326, as shown in FIG. 3J, is removed and replaced with a high-k dielectric 344. In embodiments, the first sacrificial layer 326 may be removed using an etching process. In embodiments, a high-k dielectric is a material with a higher dielectric constant as compared to silicon dioxide.

FIG. 3M shows a stage in the manufacturing process of a first embodiment variant where the second sacrificial layers 330 of FIG. 3J are attached and a metal layer 346 is inserted.

FIG. 3N shows a stage in the manufacturing process of the first embodiment variant where the seed 312 of FIG. 3M is removed, leaving partial gate stack 350 on the wafer 302.

FIG. 3O shows a stage in the manufacturing process of the first embodiment variant where an etch is performed to etch back the metal layer 346 to create cavities 348 around the metal layer 346.

FIG. 3P shows a stage in the manufacturing process of the first embodiment variant where a gate spacer 352 is inserted into the cavities 348 around the metal layers 346. A source 354 and a drain 356 may be placed on either side of the gate stack 351, which may be similar to partial gate stack 350 of FIG. 3N.

FIG. 3Q shows a stage in the manufacturing process of a second embodiment variant that may be performed subsequent to the stage described above with respect to FIG. 3L, where the seed 312 is retained and may serve as a source, which may be similar to source 354 of FIG. 3P. The second sacrificial layer 330 of FIG. 3L is partially etched away, leaving a portion of the second sacrificial layer 331 next to the seed 312. A metal layer 347 is then placed within the etched cavity next to the portion of the second sacrificial layer 331. The portion of the second sacrificial layer 331 between the metal layer 347 and the seed 312 will serve as a gate spacer.

FIG. 3R shows a stage in the manufacturing process of the second embodiment variant, where an etching process is performed to create cavities 349 at an edge of the metal layer 347.

FIG. 3S shows a stage in the manufacturing process of the second embodiment variant, where a gate spacer 353 is placed within the cavities 349 next to the metal layers 347. A drain 357, which may be similar to drain 356 of FIG. 3P, may then be applied. In embodiments, the gate spacer 353 may be made of the same material as the portion of the second sacrificial layer 331, or be made of a different material. In embodiments, the gate spacer 353 is not electrically conductive.

FIG. 4 illustrates another example transistor structure with stacked TMD layers as channels with sources and drains, in accordance with various embodiments. Transistor structure 400, which may be similar to the transistor structures of FIG. 3P or FIG. 3S, may be built using techniques with a sequence of stages similar to those described above with respect to FIGS. 3A-3S.

Transistor structure 400 may include a source 412 and a drain 457, which may be similar to source 312 and drain 457 of FIG. 3S. Various layers of dielectric 434, high-k dielectric 444, metal layers 447, gates spacers 431, 453, and single crystal TMD channels 422 may be stacked as shown. These may be similar to various layers of dielectric 334, high-k dielectric 344, metal layers 347, gates spacers 331, 353, and single crystal TMD channels 322 as shown with respect to FIGS. 3A-3S. Other stack configurations (not shown) may also be implemented using these techniques.

In embodiments, there may be volumes 422a, 422b of the single crystal TMD channels 422 that contain particles of the seed material, for example seed material 312 of FIG. 3G, at or proximate to an edge of the single crystal TMD channels 422. In embodiments, material used for the seed may include WOx or MoOx. In addition, particles of a growth promoter 423 may be found on a surface or proximate to a surface of the single crystal TMD channel 422.

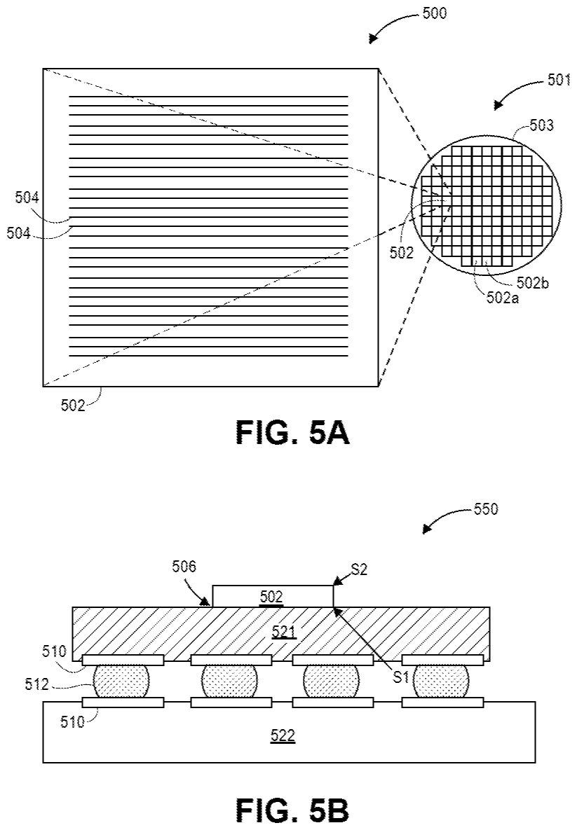

FIGS. 5A-5B schematically illustrate a top view of an example die in wafer form and in singulated form, and a cross section side view of a package assembly, in accordance with various embodiments. FIG. 5A schematically illustrates a top view of an example die 502 in a wafer form 501 and in a singulated form 500, in accordance with some embodiments. In some embodiments, die 502 may be one of a plurality of dies, e.g., dies 502, 502a, 502b, of a wafer 503 comprising semiconductor material, e.g., silicon or other suitable material. The plurality of dies, e.g., dies 502, 502a, 502b, may be formed on a surface of wafer 503. Each of the dies 502, 502a, 502b, may be a repeating unit of a semiconductor product that includes devices as described herein. For example, die 502 may include circuitry having elements such as capacitors and/or inductors 504 (e.g., fin structures, nanowires, and the like) that provide a channel pathway for mobile charge carriers in transistor devices. Although one or more capacitors and/or inductors 504 are depicted in rows that traverse a substantial portion of die 502, it is to be understood that one or more capacitors and/or inductors 504 may be configured in any of a wide variety of other suitable arrangements on die 502 in other embodiments.

After a fabrication process of the device embodied in the dies is complete, wafer 503 may undergo a singulation process in which each of dies, e.g., die 502, is separated from one another to provide discrete “chips” of the semiconductor product. Wafer 503 may be any of a variety of sizes. In some embodiments, wafer 503 has a diameter ranging from about 25.4 mm to about 450 mm. Wafer 503 may include other sizes and/or other shapes in other embodiments. According to various embodiments, the one or more capacitors and/or inductors 504 may be disposed on a semiconductor substrate in wafer form 501 or singulated form 500. One or more capacitors and/or inductors 504 described herein may be incorporated in die 502 for logic, memory, or combinations thereof. In some embodiments, one or more capacitors and/or inductors 504 may be part of a system-on-chip (SoC) assembly.

FIG. 5B schematically illustrates a cross-section side view of an integrated circuit (IC) assembly 550, in accordance with some embodiments. In some embodiments, IC assembly 550 may include one or more dies, e.g., die 502, electrically or physically coupled with a package substrate 521. Die 502 may include one or more capacitors and/or inductors 504 as described herein. In some embodiments, package substrate 521 may be electrically coupled with a circuit board 522 as is well known to a person of ordinary skill in the art. Die 502 may represent a discrete product made from a semiconductor material (e.g., silicon) using semiconductor fabrication techniques such as thin film deposition, lithography, etching, and the like. In some embodiments, die 502 may be, include, or be a part of a processor, memory, SoC or ASIC in some embodiments.

Die 502 can be attached to package substrate 521 according to a wide variety of suitable configurations including, for example, being directly coupled with package substrate 521 in a flip-chip configuration, as depicted. In the flip-chip configuration, an active side 51 of die 502 including circuitry is attached to a surface of package substrate 521 using hybrid bonding structures as described herein that may also electrically couple die 502 with package substrate 521. Active side 51 of die 502 may include multi-threshold voltage transistor devices as described herein. An inactive side S2 of die 502 may be disposed opposite to active side 51.

In some embodiments, package substrate 521 is an epoxy-based laminate substrate having a core and/or build-up layers such as, for example, an Ajinomoto Build-up Film (ABF) substrate. Package substrate 521 may include other suitable types of substrates in other embodiments including, for example, substrates formed from glass, ceramic, or semiconductor materials.

Package substrate 521 may include electrical routing features configured to route electrical signals to or from die 502. The electrical routing features may include pads or traces (not shown) disposed on one or more surfaces of package substrate 521 and/or internal routing features (not shown) such as trenches, vias, or other interconnect structures to route electrical signals through package substrate 521. In some embodiments, package substrate 521 may include electrical routing features such as pads (not shown) configured to receive the respective die-level interconnect structures 506 of die 502.

Circuit board 522 may be a printed circuit board (PCB) comprising an electrically insulative material such as an epoxy laminate. Circuit board 522 may include electrically insulating layers composed of materials such as, for example, polytetrafluoroethylene, phenolic cotton paper materials such as Flame Retardant 4 (FR-4), FR-1, cotton paper and epoxy materials such as CEM-1 or CEM-3, or woven glass materials that are laminated together using an epoxy resin prepreg material. Interconnect structures such as traces, trenches, vias may be formed through the electrically insulating layers to route the electrical signals of die 502 through circuit board 522. Circuit board 522 may comprise other suitable materials in other embodiments. In some embodiments, circuit board 522 is a motherboard as is well known to a person of ordinary skill in the art.

Package-level interconnects such as, for example, solder balls 512 may be coupled to one or more pads 510 on package substrate 521 and/or on circuit board 522 to form corresponding solder joints that are configured to further route the electrical signals between package substrate 521 and circuit board 522. Pads 510 may comprise any suitable electrically conductive material such as metal including, for example, nickel (Ni), palladium (Pd), gold (Au), silver (Ag), copper (Cu), and combinations thereof. Other suitable techniques to physically and/or electrically couple package substrate 521 with circuit board 522 may be used in other embodiments.

IC assembly 550 may include a wide variety of other suitable configurations in other embodiments including, for example, suitable combinations of flip-chip and/or wire-bonding configurations, interposers, multi-chip package configurations including system-in-package (SiP), and/or package-on-package (PoP) configurations. Other suitable techniques to route electrical signals between die 502 and other components of IC assembly 550 may be used in some embodiments.

A person of ordinary skill in the art should recognize that any known semiconductor device fabricated using any known semiconductor process that may benefit from the principles described herein.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

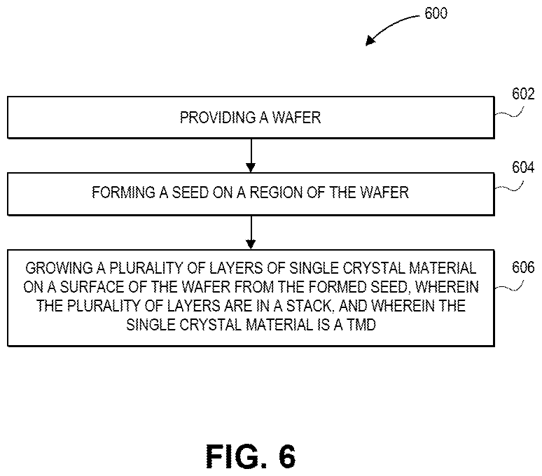

FIG. 6 is an example process for manufacturing a wafer with multiple seeds and multiple TMD layers growing from the seeds, in accordance with various embodiments. Process 600 may be implemented using the techniques and/or embodiments described herein, and in particular with respect to FIGS. 1-5B.

At block 602, the process may include providing a wafer. In embodiments, the wafer may be similar to wafer 202 of FIG. 2, wafer 302 of FIG. 3A, or wafer 503 of FIG. 5A.

At block 604, the process may further include forming a seed on a region of the wafer. In embodiments, the seed may be similar to seed 210a-210d of FIG. 2, or seed 312 of FIG. 3A.

At block 606, the process may further include growing a plurality of layers of single crystal material on a surface of the wafer from the formed seed, wherein the plurality of layers are in a stack, and wherein the single crystal material is a TMD. In embodiments, the single crystal material may be similar to TMD single crystal layer 212a-212f of FIG. 2, or TMD layer 322 of FIG. 3A.

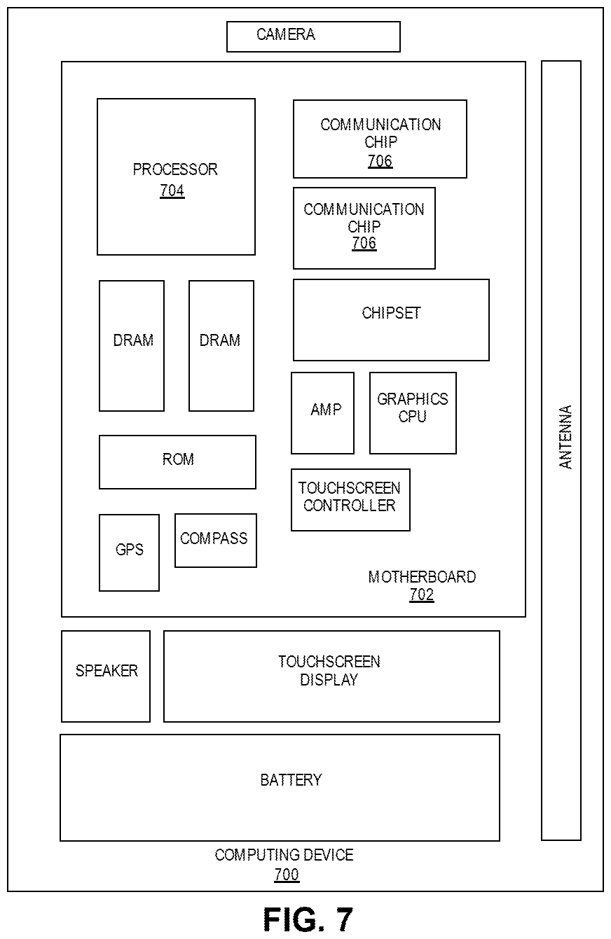

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

Depending on its applications, computing device 700 may include other components that may or may not be physically and electrically coupled to the board 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip includes one or more devices, such as MOS-FET transistors built in accordance with implementations of the invention.

In further implementations, another component housed within the computing device 700 may contain an integrated circuit die that includes one or more devices, such as MOS-FET transistors built in accordance with implementations of the invention.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

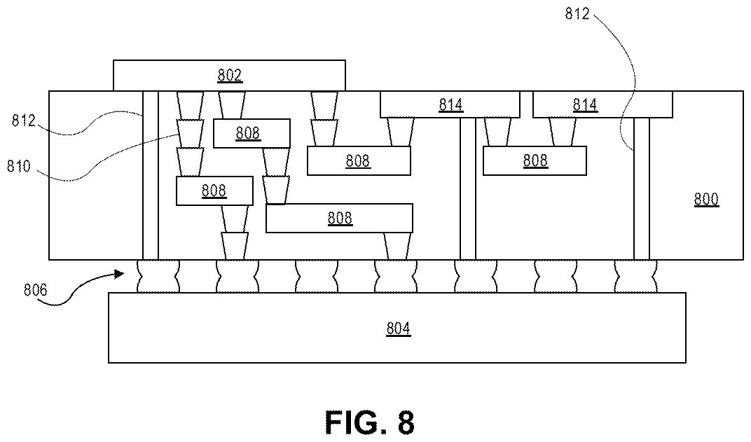

FIG. 8 illustrates an interposer 800 that includes one or more embodiments of the invention. The interposer 800 is an intervening substrate used to bridge a first substrate 802 to a second substrate 804. The first substrate 802 may be, for instance, an integrated circuit die. The second substrate 804 may be, for instance, a memory module, a computer motherboard, or another integrated circuit die. Generally, the purpose of an interposer 800 is to spread a connection to a wider pitch or to reroute a connection to a different connection. For example, an interposer 800 may couple an integrated circuit die to a ball grid array (BGA) 806 that can subsequently be coupled to the second substrate 804. In some embodiments, the first and second substrates 802/804 are attached to opposing sides of the interposer 800. In other embodiments, the first and second substrates 802/804 are attached to the same side of the interposer 800. And in further embodiments, three or more substrates are interconnected by way of the interposer 800.

The interposer 800 may be formed of an epoxy resin, a fiberglass-reinforced epoxy resin, a ceramic material, or a polymer material such as polyimide. In further implementations, the interposer 800 may be formed of alternate rigid or flexible materials that may include the same materials described above for use in a semiconductor substrate, such as silicon, germanium, and other group III-V and group IV materials.

The interposer 800 may include metal interconnects 808 and vias 810, including but not limited to through-silicon vias (TSVs) 812. The interposer 800 may further include embedded devices 814, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 800. In accordance with embodiments of the invention, apparatuses or processes disclosed herein may be used in the fabrication of interposer 800.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### Examples

Example 1 is a transistor structure comprising: a channel, wherein the channel is a single crystal material; and a dielectric layer on a top of the channel.

Example 2 includes the transistor structure of example 1, or of any other example or embodiments described herein, further comprising an edge of the channel substantially perpendicular to the top of the channel, wherein a region of the channel proximate to the edge of the channel includes one or more particles of a seed material.

Example 3 includes a transistor structure of example 1, or of any other example or embodiments described herein, wherein a bottom of the channel opposite the top of the channel region includes one or more particles of a growth promoter material.

Example 4 includes the transistor structure of example 3, or of any other example or embodiments described herein, wherein the growth promoter includes one or more of carbon rings or sodium.

Example 5 includes the transistor structure of example 1, or of any other example or embodiments described herein, wherein the single crystal material is a transition metal dichalcogenide (TMD).

Example 6 includes the transistor structure of example 5, or of any other example or embodiments described herein, wherein the single crystal material of the channel does not include a growth boundary within the single crystal material.

Example 7 includes the transistor structure of example 1, or of any other example or embodiments described herein, wherein the channel has a thickness that is less than 2.5 nm.

Example 8 includes the transistor structure of example 1, or of any other example or embodiments described herein, wherein the dielectric layer includes high-k dielectric material.

Example 9 includes the transistor structure of example 1, or of any other example or embodiments described herein, wherein the dielectric layer is a first dielectric layer, and further comprising a second dielectric layer on a bottom of the channel.

Example 10 includes the transistor structure of example 1, or of any other example or embodiments described herein, further comprising a metal layer on top of the dielectric layer.

Example 11 includes the transistor structure of example 1, or of any other example or embodiments described herein, wherein the dielectric layer is a first dielectric layer and wherein the channel is a first channel; and further comprising: a second dielectric layer on top of the metal layer; and a second channel on top of the second dielectric layer, wherein the second channel is a single crystal material.

Example 12 includes the transistor structure of example 11, or of any other example or embodiments described herein, wherein a region of the second channel proximate to an edge of the second channel includes one or more particles of a seed material.

Example 13 includes the transistor structure of example 1, or of any other example or embodiments described herein, further comprising: a source coupled with a first edge of the channel; and a drain coupled with a second edge of the channel opposite the first edge of the channel, wherein the first edge of the channel and the second edge of the channel are substantially perpendicular to the top of the channel.

Example 14 includes the transistor structure of example 13, or of any other example or embodiments described herein, wherein the source includes a seed material.

Example 15 includes the transistor structure of example 14, or of any other example or embodiments described herein, wherein the channel is grown from the seed material.

Example 16 is an apparatus comprising: a wafer; a seed material on the wafer, wherein a top of the seed material is at a first height above a surface of the wafer; a layer of single crystal material grown on a surface of the wafer and at least partially physically coupled with the seed material, wherein a top of the layer of single crystal material is at a second height above the surface of the wafer; and wherein the first height is greater than the second height.

Example 17 includes the apparatus of example 16, or of any other example or embodiments described herein, further including a layer of growth promoter material between a bottom of the layer of single crystal material opposite the top of the layer of single crystal material and the surface of the wafer.

Example 18 includes the apparatus of example 16, or of any other example or embodiments described herein, further comprising: a first sacrificial layer on top of the layer of single crystal material; a second sacrificial layer on top of the first sacrificial layer; and a dielectric layer on top of the second sacrificial layer.

Example 19 includes the apparatus of example 16, or of any other example or embodiments described herein, wherein the layer of single crystal material is a first layer; and further comprising a second layer of single crystal material grown on a top of the dielectric layer, wherein the second layer of single crystal material is at least partially physically coupled with the seed material.

Example 20 includes the apparatus of example 19, or of any other example or embodiments described herein, further comprising a layer of growth promoter material between a bottom of the second layer of single crystal material and the top of the dielectric layer.

Example 21 includes the apparatus of example 16, or of any other example or embodiments described herein, wherein the layer of single crystal material is a TMD.

Example 22 is a method comprising: providing a wafer; forming a seed on a region of the wafer; and growing a plurality of layers of single crystal material on a surface of the wafer from the formed seed, wherein the plurality of layers are in a stack, and wherein the single crystal material is a transition metal dichalcogenide (TMD).

Example 23 includes the method of example 22, or of any other example or embodiments described herein, further comprising forming a layer of growth promoter on the surface of the wafer.

Example 24 includes the method of example 22, or of any other example or embodiments described herein, wherein the seed is a plurality of seeds and the plurality of layers of single crystal material is a plurality of the plurality of layers of single crystal material.

Example 25 includes the method of example 22, or of any other example or embodiments described herein, wherein the layer of single crystal material has a thickness that is less than 2.5 nm.

What is claimed is:

1. A transistor structure comprising:
a channel, wherein the channel is a single crystal material; and
a dielectric layer on a top of the channel.

2. The transistor structure of claim 1, further comprising an edge of the channel substantially perpendicular to the top of the channel, wherein a region of the channel proximate to the edge of the channel includes one or more particles of a seed material.

3. The transistor structure of claim 1, wherein a bottom of the channel opposite the top of the channel includes one or more particles of a growth promoter material.

4. The transistor structure of claim 3, wherein the growth promoter material includes a selected one or more of: carbon rings or sodium.

5. The transistor structure of claim 1, wherein the single crystal material is a transition metal dichalcogenide (TMD).

6. The transistor structure of claim 5, wherein the single crystal material does not include a growth boundary.

7. The transistor structure of claim 1, wherein the channel has a thickness that is less than 2.5 nm.

8. The transistor structure of claim 1, wherein the dielectric layer includes high-k dielectric material.

9. The transistor structure of claim 1, wherein the dielectric layer is a first dielectric layer, and further comprising a second dielectric layer on a bottom of the channel.

10. The transistor structure of claim 1, further comprising a metal layer on top of the dielectric layer.

11. The transistor structure of claim 10, wherein the dielectric layer is a first dielectric layer and wherein the channel is a first channel; and further comprising:
a second dielectric layer on top of the metal layer; and
a second channel on top of the second dielectric layer, wherein the second channel is a single crystal material.

12. The transistor structure of claim 11, wherein a region of the second channel proximate to an edge of the second channel substantially perpendicular to the top of the channel includes one or more particles of a seed material.

13. The transistor structure of claim 1, further comprising:
a source coupled with a first edge of the channel; and
a drain coupled with a second edge of the channel opposite the first edge of the channel, wherein the first edge of the channel and the second edge of the channel are substantially perpendicular to the top of the channel.

14. The transistor structure of claim 13, wherein the source includes a seed material.

15. The transistor structure of claim 14, wherein the channel is grown from the seed material.

16. An apparatus comprising:
a wafer;
a seed material on the wafer, wherein a top of the seed material is at a first height above a surface of the wafer;
a layer of single crystal material grown on a surface of the wafer and at least partially physically coupled with the seed material, wherein a top of the layer of single crystal material is at a second height above the surface of the wafer; and
wherein the first height is greater than the second height.

17. The apparatus of claim 16, further including a layer of growth promoter material between a bottom of the layer of single crystal material opposite the top of the layer of single crystal material and the surface of the wafer.

18. The apparatus of claim 16, further comprising:
a first sacrificial layer on top of the layer of single crystal material;
a second sacrificial layer on top of the first sacrificial layer; and
a dielectric layer on top of the second sacrificial layer.

19. The apparatus of claim 16, wherein the layer of single crystal material is a first layer; and further comprising a second layer of single crystal material grown on a top of the dielectric layer, wherein the second layer of single crystal material is at least partially physically coupled with the seed material.

20. The apparatus of claim 19, further comprising a layer of growth promoter material between a bottom of the second layer of single crystal material and the top of the dielectric layer.

21. The apparatus of claim 16, wherein the layer of single crystal material is a TMD.

22. A method comprising:
providing a wafer;
forming a seed on a region of the wafer; and
growing a plurality of layers of single crystal material on a surface of the wafer from the formed seed, wherein the plurality of layers are in a stack, and wherein the single crystal material is a transition metal dichalcogenide (TMD).

23. The method of claim 22, further comprising forming a layer of growth promoter on the surface of the wafer.

24. The method of claim 22, wherein the seed is a plurality of seeds and the plurality of layers of single crystal material is a plurality of the plurality of layers of single crystal material.

25. The method of claim 22, wherein the layer of single crystal material has a thickness that is less than 2.5 nm.
